(19) United States
(12) Patent Application Publication
(10) Pub. No.: US 2008/0032484 A1
(43) Pub. Date: Feb. 7, 2008

(54) Substrate bonding process with integrated vents

(75) Inventors: Buu Quoc Diep, Murphy, TX (US); Osvaldo Enriquez, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED

(21) Appl. No.: 11/499,080

(22) Filed: Aug. 4, 2006

(51) Int. Cl. H01L 21/30

(52) U.S. Cl. 438/455

(57) ABSTRACT

In one method embodiment, a method for bonding a capping substrate to a base substrate comprises providing a capping substrate with a plurality of vents extending through the capping substrate and sealing the capping substrate to the base substrate.

In one embodiment, an apparatus comprising a base substrate, a capping substrate sealed to the base substrate and formed with a plurality of vents extending through the capping substrate, and sealant closing each of the plurality of vents.

### TECHNICAL FIELD OF THE INVENTION

This invention relates in general to controlling pressures associated with bonding substrates together, and, in particular, to an improved method of manufacturing the same.

### BACKGROUND OF THE INVENTION

Within the semiconductor industry, numerous applications require bonding substrates together. For example, a microelectromechanical system (MEMS) device formed in or on a semiconductor wafer is often capped by a second wafer or glass substrate, forming a package comprising a cavity that protects and encloses the MEMS device. Examples of MEMS devices protected in this manner include digital micromirrors (DMD), pressure sensors, and accelerometers etc. Certain MEMS devices, such as DMDs, have conductive runners electrically interconnected to bond pads that are external to the sealed cavity. In many applications, these bond pads must also be sealed within the bonded substrate assembly in order to continue conventional assembly and packing processes that might otherwise corrode or oxidize the bond pads.

### OVERVIEW OF EXAMPLE EMBODIMENTS

In one method embodiment, a method for bonding a capping substrate to a base substrate comprises providing a capping substrate with a plurality of vents extending through the capping substrate and sealing the capping substrate to the base substrate.

In one embodiment, an apparatus comprising a base substrate, a capping substrate sealed to the base substrate and formed with a plurality of vents extending through the capping substrate, and sealant closing each of the plurality of vents.

Depending on the specific features implemented, particular embodiments of the present invention may exhibit some, none, or all of the following technical advantages. Various embodiments may be capable of providing a method of controlling the air pressures associated with bonding substrates together. Some embodiments may facilitate automation associated with sealing the bonded substrate assembly. Other technical advantages will be readily apparent to one skilled in the art from the following figures, description and claims. Moreover, while specific advantages have been enumerated, various embodiments may include all, some or none of the enumerated advantages.

### BRIEF DESCRIPTION OF THE DRAWINGS

For a more complete understanding of the present invention, and for further features and advantages thereof, reference is now made to the following description taken in conjunction with the accompanying drawings, in which:

FIG. 1 is a top view of a conventional dispense pattern of epoxy on a digital micromirror device wafer.

FIG. 2A is a top view of one embodiment of a base substrate.

FIG. 2B is a cross sectional view illustrating one example of a method of bonding a capping substrate to a base substrate.

FIG. 3 is a flow chart illustrating one example of a method of bonding a capping substrate to a base substrate.

### DETAILED DESCRIPTION OF EXAMPLE EMBODIMENTS

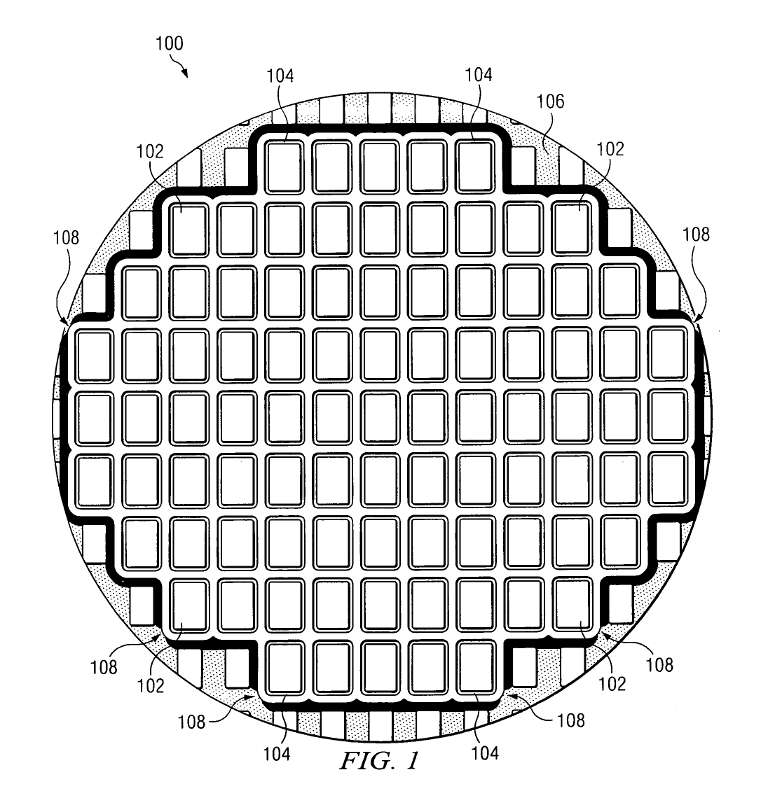

Particular examples and dimensions specified throughout this document are intended for example purposes only, and are not intended to limit the scope of the present disclosure. In particular, this document is not intended to be limited to bonding particular substrates together, such as a DMD substrate to a glass substrate. Moreover, the illustrations in FIGS. 1 through 3 are not intended to be to scale.

FIG. 1 is a top view of a conventional dispense pattern of epoxy on a semiconductor wafer 100 that comprises a plurality of digital micromirror devices (DMD) 102. The epoxy pattern forms a perimeter 104 around each DMD 102 that seals the microelectromechanical system (MEMS) portion of each DMD die 102. In addition, the epoxy pattern comprises an incomplete epoxy perimeter 106 around semiconductor wafer 100 with a plurality of openings 108. The openings 108 release air pressure buildup resulting from bonding semiconductor wafer 100 to a glass substrate (not explicitly shown) that might otherwise compromise sealant perimeters 104. Bonding semiconductor wafer 100 to a glass substrate forms a bonded substrate assembly comprising a plurality of packages, each package comprising a cavity that protects and encloses the MEMS portion of each DMD die 102. Each DMD die 102 has conductive runners electrically connected to bond pads (not explicitly shown) external to its respective epoxy perimeter 104. Because the open openings 108 expose the bond pads to the outside environment, at some point each opening 108 is typically sealed to continue conventional assembly processing of the DMDs that might otherwise corrode or oxidize the bond pads. Sealing openings 108 completes epoxy perimeter 106 around semiconductor wafer 100, thereby protecting the bond pads while strengthening the seal between substrates.

Conventional processing associated with sealing openings 108 has limited manufacturability for a variety of reasons. For example, each opening 108 is typically sealed manually. This limitation is partially due to automation costs associated with accessing the sides of the bonded substrate assembly. Another reason is the location and dimensional dependency of each opening 108 upon the repeatability of the epoxy dispensing process.

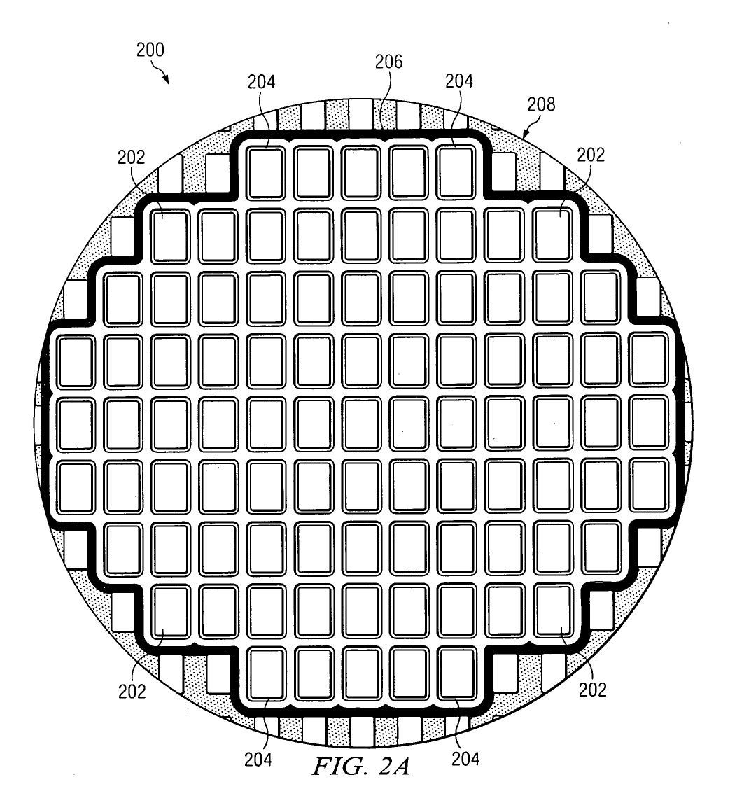

FIG. 2A is a perspective view of one embodiment of forming a substrate assembly 200 by bonding a capping substrate (not explicitly shown) to a base substrate 208 according to the teachings of the invention. Capping substrate and base substrate 208 may comprise any suitable material used in semiconductor fabrication and packaging, such as silicon, poly-silicon, indium phosphide, germanium, gallium arsenide, or glass. In this example, base substrate 208 comprises a plurality of digital micromirror device (DMD) die 202 disposed outwardly from a CMOS wafer. Although this example uses DMDs 202, any semiconductor die and/or micromachined structure, including any microelectromechancial system (MEMS), may be used without departing from the scope of the present disclosure.

In this example, base substrate 208 further comprises a sealant disposed outwardly from base substrate 208 that forms a complete sealant perimeter 204 around at least a portion, in this example the microelectromechanical system (MEMS) portion, of each DMD die 202. In addition, base substrate 208 further comprises a complete sealant perimeter 206 around base substrate 208. Sealant perimeters 204 and 206 may comprise any suitable material used to bond substrates together. In this example, sealant perimeters 204 and 206 both comprise an epoxy that may be cured by ultraviolet light (UV). Each DMD die 202 has conductive runners electrically connected to bond pads (not explicitly shown) external to its respective sealant perimeter 204.

Because sealant perimeter 206 forms a complete perimeter around base substrate 200, sealant perimeter 206 avoids conventional process limitations associated with an incomplete perimeter. Forming sealant perimeters 204 and 206 may be effected through any of a variety of processes. For example, sealant perimeters 204 and 206 may be formed by dispensing epoxy using automated equipment, such as, for example, equipment associated with jetting technology.

FIG. 2B is a cross sectional view illustrating one example of a method of forming a portion of substrate assembly 200 by bonding a capping substrate 216 to base substrate 208. In this example, capping substrate 216 comprises a glass wafer. Although this example uses a glass wafer, other substrates may be used without departing from the scope of the present disclosure. In this example, sealant perimeter 204 and an interposer layer 212 enclose at least a portion of DMD 202 within a cavity 210 between capping substrate 216 and base substrate 208, thereby forming a protective package. Interposer layer 212 may comprise any suitable material used to space at least a portion of capping substrate 216 from at least a portion of base substrate 208. In this particular example, interposer layer 212 comprises a grid of glass sealed to capping substrate 216 by UV cured epoxy. In other embodiments, interposer layers may be formed by selectively removing a portion of capping substrate 216, and/or by coupling an interposer layer to base substrate 208 prior to bonding substrates 216 and 208 together.

In this example, a plurality of vents 214 release a buildup of pressure resulting from bonding substrates 216 and 208 together. Forming vents 214 may be effected through any of a variety of processes. In this particular example, vents 214 are formed by drilling a hole through capping substrate 216 and interposer layer 212 at some point prior to bonding capping substrate 216 to base substrate 208. In other embodiments, vents 214 may form an opening in cavity 210 disposed outwardly from a non-functional die coupled to base substrate 208. Although vents 214 are shown as being formed through capping substrate 216 and interposer layer 212, any vent that extends through capping substrate 216 and/or base substrate 208 may be formed without departing from the scope of the present disclosure.

In this example, at some point vents 214 are sealed. Sealing vents 214 may be effected through any of a variety of processes. For example, vents 214 may be sealed by forming a sealing cap 322 outwardly from and/or within vents 214. In this particular example, vents 214 are sealed by dispensing an epoxy cap 218 on the outwardly disposed surface of capping substrate 216. One aspect of this disclosure recognizes that the formation and sealing of vents 214 may be effected by high-precision, automated equipment. In addition, vents 214 and sealant cap 218 may coincide with or be aligned relative to elements used to align capping substrate 216 to base substrate 208.

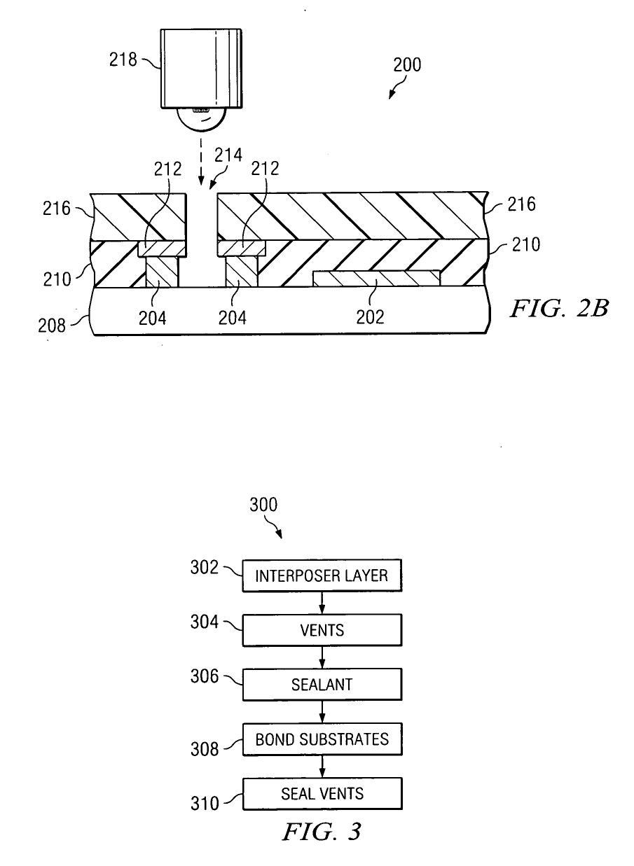

FIG. 3 is a flow chart 300 illustrating one example of a method of bonding a capping substrate to a base substrate. Method 300 beings in step 302, in which an interposer layer is formed on at least a portion of the capping substrate surface. In step 304, a plurality of vents are formed that extend through the capping substrate and the interposer layer. Next, in step 306 a sealant is formed on the base substrate layer in a pattern that corresponds to the interposer layer. Step 308 involves bonding the capping substrate to the base substrate. In the final step 310, the vents are externally sealed.

Although the present invention has been described in several embodiments, a myriad of changes, variations, alterations, transformations, and modifications may be suggested to one skilled in the art, and it is intended that the present invention encompass such changes, variations, alterations, transformations, and modifications as falling within the spirit and scope of the appended claims.

What is claimed is:

1. A method for bonding a capping substrate to a base substrate, comprising:
separating at least a portion of the capping substrate from at least a portion of the base substrate by an interposer layer;
providing a plurality of vents extending through the capping substrate and through the interposer layer;
sealing the capping substrate to the base substrate, including sealing a first sealed perimeter around the base substrate and sealing a plurality of second sealed perimeters within the first sealed perimeter; and
sealing the vents after the capping substrate is sealed to the base substrate.

2. The method of claim 1, wherein providing a plurality of vents extending through the capping substrate comprises providing vents that are capable of relieving air pressure associated with bonding the capping substrate to the base substrate.

3. The method of claim 1, wherein sealing the capping substrate to the base substrate comprises sealing a capping substrate to a semiconductor wafer comprising a plurality of semiconductor devices; and
wherein sealing a plurality of second sealed perimeters within the first sealed perimeter comprises sealing a perimeter around at least a portion of each semiconductor device.

4. A method for bonding a capping substrate to a base substrate, comprising:
providing a capping substrate with a plurality of vents extending through the capping substrate; and
sealing the capping substrate to the base substrate.

5. The method of claim 4, wherein providing a plurality of vents extending through the capping substrate comprises providing a plurality of vents that are capable of relieving air pressure associated with bonding the capping substrate to the base substrate.

6. The method of claim 4, wherein bonding the capping substrate to the base substrate comprises sealing the plurality of vents extending through the capping substrate.

7. The method of claim 6, wherein sealing the plurality of vents extending through the capping substrate comprises applying a sealant by automated tools.

8. The method of claim 4, wherein sealing the capping substrate to a base substrate comprises sealing glass to the base substrate.

9. The method of claim 4, wherein sealing the capping substrate to a base substrate comprises sealing a capping substrate to a semiconductor wafer comprising a plurality of semiconductor devices.

10. The method of claim 9, wherein providing a plurality of vents extending through the capping substrate comprises providing at least one vent formed outwardly from a non-functional semiconductor device.

11. The method of claim 9, wherein sealing a capping substrate to a semiconductor wafer comprises sealing a perimeter around at least a portion of each semiconductor device.

12. The method of claim 11, wherein providing a plurality of vents extending through the capping substrate comprises providing a plurality of vents exterior to the sealed perimeters around at least a portion of each semiconductor device.

13. An apparatus comprising:
a base substrate;
a capping substrate sealed to the base substrate and formed with a plurality of vents extending through the capping substrate; and
and sealant closing each of the plurality of vents.

14. The apparatus of claim 13, wherein the capping substrate comprises glass.

15. The apparatus of claim 13, wherein the base substrate comprises a semiconductor wafer.

16. The apparatus of claim 15, wherein the semiconductor wafer comprises a plurality of semiconductor devices.

17. The apparatus of claim 16, wherein the plurality of semiconductor devices comprises a plurality of digital micromirror devices.

18. The apparatus of claim 16, wherein at least a portion of each semiconductor device is sealed within a cavity formed at least in part by a sealant coupling the capping substrate to the base substrate.

19. The apparatus of claim 18, wherein each vent is exterior to each cavity.

20. The apparatus of claim 18, wherein at least one vent is disposed outwardly from a non-functional semiconductor device.
